(19) United States
(12) Patent Application Publication
(10) Pub. No.: US 2004/0204164 A1
(43) Pub. Date: Oct. 14, 2004

(54) Information communicating device for vehicles

(76) Inventor: Hsiu Chu Hsu Li, Hsin Chuang City (TW)

Correspondence Address: Hsiu Chu HSU LI, P.O.Box 4-67, Hsin Chuang, Taipei, 242, TW

(21) Appl. No.: 10/253,303

(22) Filed: Sep. 20, 2002

(51) Int. Cl. H04B 1/06; H05K 11/02; H04M 1/00; H04B 1/38

(52) U.S. Cl. 455/569.1; 455/345

(57) ABSTRACT

An information communicating device for vehicles includes a housing having a seat for supporting phones, and having an emergent key for dialing emergent calls, a vocal key for switching to a vocal dialing mode, a traffic condition key for receiving traffic condition, and a phone receiving key for receiving phone call without carrying the phones. A primary control unit is received in the housing, and coupled to the keys, a voice control unit coupled to the primary control unit, and a power supply unit for supplying electric power to the primary control unit and the voice control unit.

### BACKGROUND OF THE INVENTION

1. Field of the Invention

The present invention relates to an information communicating device, and more particularly to an information communicating device for attaching to vehicles and for allowing users to easily and quickly dial the required or emergent phones.

2. Description of the Prior Art

Various kinds of typical information communicating devices have been provided or attached to the vehicles, for allowing the drivers or the users to speak the phones without carrying or picking up the hand sets of the portable or mobile phones. However, the users, particularly the drivers also have to dial the phones, such as the emergent phones. It will be dangerous for the users or the drivers to dial the phones, particularly while driving the vehicles.

The present invention has arisen to mitigate and/or obviate the afore-described disadvantages of the conventional vehicle information communicating devices.

### SUMMARY OF THE INVENTION

The primary objective of the present invention is to provide an information communicating device for attaching to vehicles and for allowing users to easily and quickly dial the required or emergent phones.

In accordance with one aspect of the invention, there is provided an information communicating device for vehicles, the information communicating device comprising a housing including a supporting seat provided thereon for supporting portable phones, and including an emergent key for dialing an emergent call, and a vocal key for switching to a vocal dialing mode, and a traffic condition key for receiving traffic condition, and a phone receiving key for receiving phone call without carrying the portable phones, and including a microphone and a speaker, and including a knob for adjusting volume of the speaker, a primary control unit received in the housing, and coupled to the emergent key and the vocal key and the traffic condition key and the phone receiving key, a voice control unit coupled to the primary control unit, and including at least one ear piece, for controlling output voice from the portable phones and the at least one ear piece and the speaker, and a power supply unit for supplying electric power to energize the primary control unit and the voice control unit.

The primary control unit further includes a key control circuit coupled to the emergent key and the vocal key and the traffic condition key and the phone receiving key, a CPU control circuit coupled to the key control circuit, a transforming circuit coupled to the CPU control circuit, and a phone transmission interface coupled to the transforming circuit.

The primary control unit further includes an energy economizing circuit coupled to the CPU control circuit, and/or a power stabilizing circuit coupled to the phone transmission interface.

The power supply unit includes a filtering circuit for coupling to an electric power source for receiving an electric power, and including a stabilizing circuit coupled to the filtering circuit for converting the electric power from the filtering circuit to an 5V electric power, and for providing the 5V electric power to the key control circuit and the CPU control circuit and the transforming circuit.

The voice control unit includes at least one amplifying circuit, an echo echo control circuit, and a is microphone silence control circuit.

The filtering circuit of the power supply unit may include a further stabilizing circuit coupled to the filtering circuit for converting the electric power from the filtering circuit to an 8V electric power, and for providing the 8V electric power to the voice control unit.

The housing further includes a silence key for silencing the microphone and the speaker and the at least one ear piece, and/or an information receiving key for dialing to internet service providers, and/or a radio station key for dialing to selected radio stations.

Further objectives and advantages of the present invention will become apparent from a careful reading of a detailed description provided hereinbelow, with appropriate reference to accompanying drawings.

### BRIEF DESCRIPTION OF THE DRAWINGS

FIG. 1 is a perspective view of an information communicating device in accordance with the present invention;

FIG. 2 is a top plan view of the information communicating device;

FIG. 3 is a side plan view of the information communicating device; and

FIG. 4 is a block diagram illustrating the circuits or the devices of the information communicating device for vehicles.

### DETAILED DESCRIPTION OF THE PREFERRED EMBODIMENT

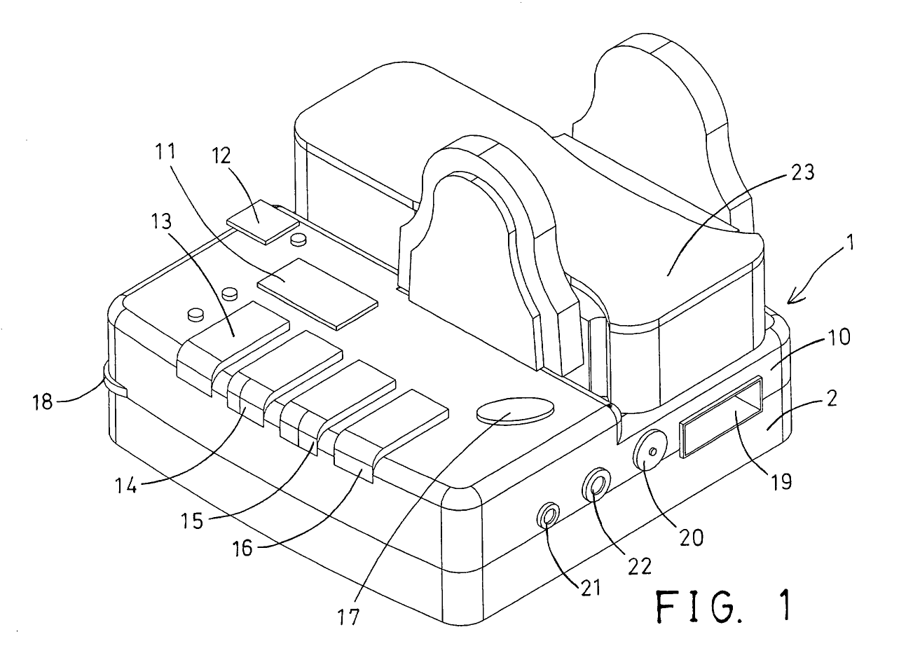

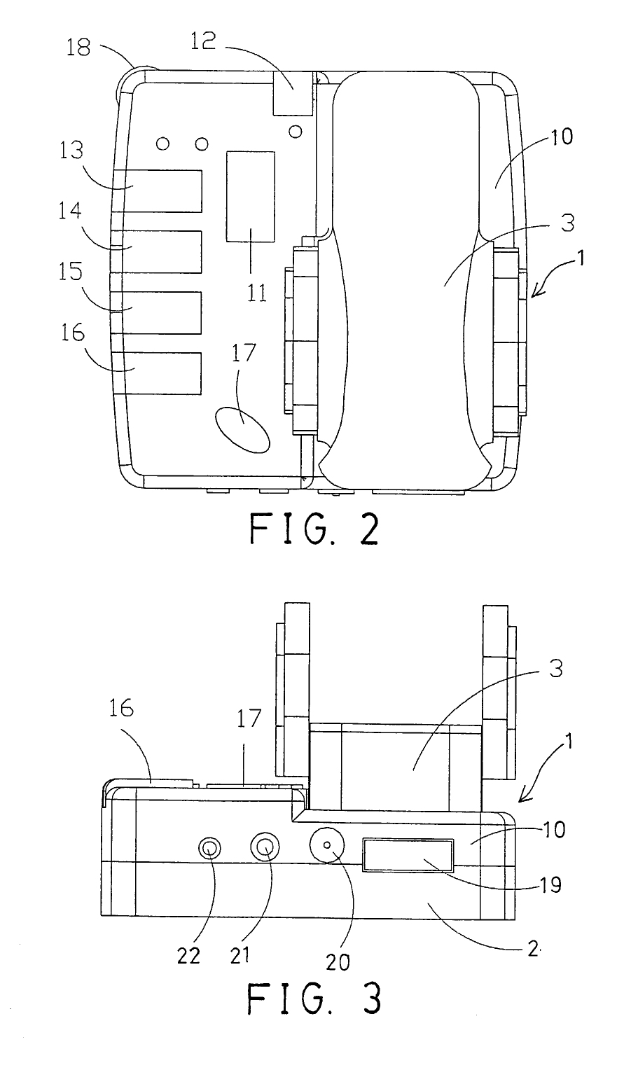

Referring to the drawings, and initially to FIGS. 1-3, an information communicating device in accordance with the present invention comprises a housing 1 including an upper casing 10 and a lower casing 2 that may be secured together by such as force-fitted engagements, adhesive materials, fasteners, or by welding processes.

The housing 1 includes an emergent key 11, a silence key 12, a vocal key 13, an information receiving key 14, a traffic condition key 15, a traffic radio station key 16, and a phone pick up key 17 provided thereon, such as provided on the upper casing 10 thereof.

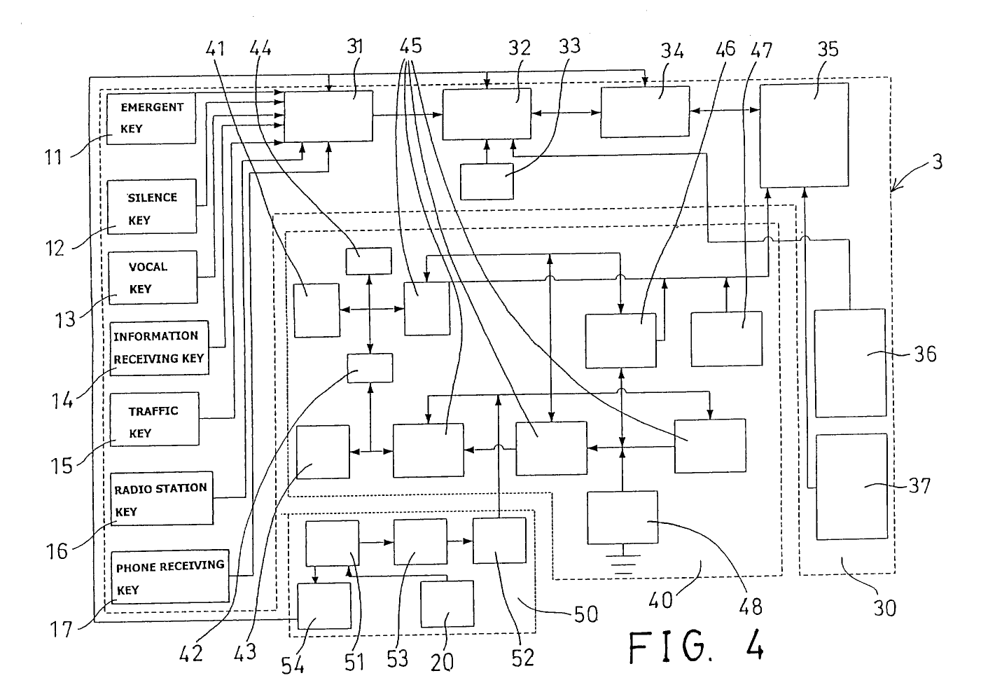

The housing 1 further includes a socket 19 for coupling to the portable or mobile phones, another socket 20 for coupling to the electric power sources, such as the electric power sources of the vehicles, and two further sockets 21, 22 for coupling to the microphones 41 and the ear pieces 42 (FIG. 4) respectively.

The housing 1 may further include a volume knob 18 for adjusting the volume of the information communicating device, and may further include a supporting seat 23 provided thereon for supporting such as the hand sets of the portable or mobile phones (not shown).

The information communicating device includes a control circuit or device 3 (FIG. 4) that may be disposed within the housing 1. The control device 3 includes a primary control unit 30 having a key control circuit 31 coupled to the keys 11-17, and/or the knob 18, and includes a central processing unit (CPU) control circuit 32 coupled to the key control circuit 31.

A resetting circuit 33 may be coupled to the CPU control circuit 32 for resetting purposes. A circuit, such as an R323 transforming circuit 34 may be provided and coupled to the CPU control circuit 32, and coupled to a phone transmission interface 35.

The primary control unit 30 may further include an energy economizing circuit 36 and/or a power stabilizing circuit 37 coupled to the CPU control circuit 32 and the phone transmission interface 35 respectively for allowing the primary control unit 30 of the control device 3 to be suitably operated or energized.

The information communicating device further includes a sound or voice control unit 40 having the microphones 41 and the ear pieces 42 provided therein for speaking the phones and for hearing the phones respectively. The sound or voice control unit 40 further includes a horn or a speaker 43 for amplifying the sound or voice of the phones.

The sound or voice control unit 40 may further include one or more amplifying circuits 45 for amplifying the sound or voice of the phones, and for allowing the phones to be clearly heard via the speaker 43 or the ear pieces 42.

The sound or voice control unit 40 may further include an echo control circuits 46 and/or a microphone silence control circuit 47 and/or an output level adjusting circuit 48, for further facilitating the receiving or hearing of the phones.

The information communicating device further includes a power supply unit 50 having a filtering circuit 51 coupled to the socket 20, for receiving a power input, such as a 12V power source from the vehicle.

The power supply unit 50 may include a stabilizing circuit 52 coupled to the filtering circuit 51, for receiving such as an 8V electric power from the filtering circuit 51, or for converting the electric power from the filtering circuit to 8V electric power, and for providing the electric power to the sound or voice control unit 40.

The power supply unit 50 may include a further stabilizing circuit 54 coupled to the filtering circuit 51, for receiving such as a 5V electric power from the filtering circuit 51, or for converting the electric power from the filtering circuit to 5V electric power, and for providing the electric power to the key control circuit 31 and/or the CPU control circuit 32 and/or the R323 transforming circuit 34.

In operation, as shown in FIG. 4, the depression or the actuation of the emergent key 11 may be used for dialing one or more preset emergent phones which have the priority to be dialed even when a phone has been entered into and received by the information communicating device.

When the silence key 12 is depressed or actuated, the speaker 43 and/or the ear pieces 42 and/or the microphones 41 may be silenced. The speaker 43 and/or the ear pieces 42 and/or the microphones 41 may be actuated or energized again when the silence key 12 is depressed again, for example.

When the vocal key 13 is depressed or actuated, a vocal dialing mode may be selected, or the portable or mobile phones may be dialed with voices or sounds without picking up the hand sets of the portable or mobile phones, such that the users or the drivers may use or speak the phones without picking up the hand sets of the portable or mobile phones.

When the information receiving key 14 is depressed or actuated, the portable or mobile phones may be dialed or coupled to various internet service providers (ISP) for receiving the information or services or inquiries from the ISPs.

When the traffic condition key 15 is depressed or actuated, the portable or mobile phones may be dialed or coupled to the preset traffic information providers or stations for receiving or checking the required traffic conditions.

When the radio station key 16 is depressed or actuated, the portable or mobile phones may be dialed or coupled to various or selected radio stations for hearing the musics or various information from various radio stations.

When the phone receiving key 17 is depressed or actuated, the hand sets of the portable or mobile phones or the microphones 41 or the ear pieces 42 or the speakers 43 of the information communicating device may be actuated or energized for receiving the phones.

The hand sets of the portable or mobile phones or the microphones 41 or the ear pieces 42 or the speakers 43 of the information communicating device may be switched off or hung up when the phone receiving key 17 is depressed again, for example.

It is to be noted that the users or the drivers may easily and quickly dial to various required phones without dialing the hand sets, such that the users, particularly the drivers may much more safely speak or receive or dial the phones without pay much attention to dial or to depress the keys of the hand sets.

Accordingly, the information communicating device in accordance with the present invention may be used for attaching to vehicles and for allowing users or the drivers to easily and quickly dial the required or emergent phones.

Although this invention has been described with a certain degree of particularity, it is to be understood that the present disclosure has been made by way of example only and that numerous changes in the detailed construction and the combination and arrangement of parts may be resorted to without departing from the spirit and scope of the invention as hereinafter claimed.

I claim:

1. An information communicating device for vehicles, said information communicating device comprising:
a housing including a supporting seat provided thereon for supporting portable phones, and including an emergent key for dialing an emergent call, and including a vocal key for switching to a vocal dialing mode, and including a traffic condition key for receiving traffic condition, and including a phone receiving key for receiving phone call without carrying the portable phones, and including a microphone and a speaker, and including a knob for adjusting volume of said speaker,
a primary control unit received in said housing, and coupled to said emergent key and said vocal key and said traffic condition key and said phone receiving key,
a voice control unit coupled to said primary control unit, and including at least one ear piece, for controlling output voice from said portable phones and said at least one ear piece and said speaker, and
a power supply unit for supplying electric power to energize said primary control unit and said voice control unit.

2. The information communicating device according to claim 1, wherein said primary control unit further includes a key control circuit coupled to said emergent key and said vocal key and said traffic condition key and said phone receiving key, a CPU control circuit coupled to said key control circuit, a transforming circuit coupled to said CPU control circuit, and a phone transmission interface coupled to said transforming circuit.

3. The information communicating device according to claim 2, wherein said primary control unit further includes an energy economizing circuit coupled to said CPU control circuit.

4. The information communicating device according to claim 2, wherein said primary control unit further includes a power stabilizing circuit coupled to said phone transmission interface.

5. The information communicating device according to claim 2, wherein said power supply unit includes a filtering circuit for coupling to an electric power source for receiving an electric power, and including a stabilizing circuit coupled to said filtering circuit for converting said electric power from the filtering circuit to an 5V electric power, and for providing said 5V electric power to said key control circuit and said CPU control circuit and said transforming circuit.

6. The information communicating device according to claim 1, wherein said voice control unit includes at least one amplifying circuit, an echo echo control circuit, and a microphone silence control circuit.

7. The information communicating device according to claim 1, wherein said power supply unit includes a filtering circuit for coupling to an electric power source for receiving an electric power, and including a stabilizing circuit coupled to said filtering circuit for converting said electric power from the filtering circuit to an 8V electric power, and for providing said 8V electric power to said voice control unit.

8. The information communicating device according to claim 1, wherein said housing further includes a silence key for silencing said microphone and said speaker and said at least one ear piece.

9. The information communicating device according to claim 1, wherein said housing further includes an information receiving key for dialing to internet service providers.

10. The information communicating device according to claim 1, wherein said housing further includes a radio station key for dialing to selected radio stations.
